(19) United States
(12) Patent Application Publication
(10) Pub. No.: US 2025/0248093 A1
(43) Pub. Date: Jul. 31, 2025

(54) DOPING PROFILE OF P-TYPE GALLIUM NITRIDE LAYER

(71) Applicant: NAVITAS SEMICONDUCTOR LIMITED, Dublin (IE)

(72) Inventors: Santosh Sharma, Austin, TX (US); Nick Fichtenbaum, Torrance, CA (US); Zhanbo Xia, Torrance, CA (US)

(73) Assignee: NAVITAS SEMICONDUCTOR LIMITED, Dublin (IE)

(21) Appl. No.: 19/040,005

(22) Filed: Jan. 29, 2025

Related U.S. Application Data
(60) Provisional application No. 63/626,972, filed on Jan. 30, 2024.
(60) Provisional application No. 63/551,498, filed on Feb. 8, 2024.
(60) Provisional application No. 63/696,722, filed on Sep. 19, 2024.

(51) Int. Cl. H10D 62/85; H10D 62/852

(52) U.S. Cl. CPC H10D 62/8503; H10D 62/852

(57) ABSTRACT

A substrate includes a first layer comprising aluminum gallium nitride (AlGaN) and a second layer disposed on the first layer. The second layer includes gallium nitride (GaN), hydrogen and a p-type dopant, the second layer having a top region disposed above a bottom region. Within the top region an average concentration of hydrogen is within one order of magnitude of the p-type dopant and within the bottom region an average concentration of hydrogen is less than an average concentration of the p-type dopant by at least one order of magnitude.

### CROSS-REFERENCES TO OTHER APPLICATIONS

This application claims priority to U.S. provisional patent application Ser. No. 63/626,972, for “METHOD FOR ANNEALING GALLIUM-NITRIDE SUBSTRATE WITH P-TYPE LAYER” filed on Jan. 30, 2024, U.S. provisional patent application Ser. No. 63/551,498, for “DOPING PROFILE OF P-TYPE GaN” filed on Feb. 8, 2024 and U.S. provisional patent application Ser. No. 63/696,722, for “DOPING PROFILE OF P-TYPE GaN” filed on Sep. 19, 2024, all of which are hereby incorporated by reference in their entirety for all purposes.

### FIELD

The described embodiments relate generally to semiconductor substrates that are formed from gallium nitride (GaN). More particularly, the present embodiments relate to gallium nitride (GaN)-based semiconductor substrates that include a p-type conductivity layer that has varying concentrations of the p-type dopant and a dopant deactivation agent.

### BACKGROUND

Currently there are a wide variety of semiconductor substrates that can be used for fabricating transistors, one of which is gallium nitride (GaN). To improve performance characteristics of the transistors it is generally beneficial to have transistors with a low leakage current (e.g., reduced forward gate current) and an improved subthreshold slope (e.g., the transistor blocks current at a reduced voltage below the gate threshold voltage). However, achieving reduced leakage current and subthreshold slope can be difficult without adversely affecting other performance parameters of the transistors.

New transistors require reduced leakage current and improved subthreshold slope without adversely affecting other performance parameters to meet the needs of new electronic systems.

### SUMMARY

Summary A substrate includes a first layer comprising aluminum gallium nitride (AlGaN) and a second layer disposed on the first layer. The second layer includes gallium nitride (GaN), hydrogen, and a p-type dopant, the second layer having a top region disposed above a bottom region. Within the top region, an average concentration of hydrogen is within one order of magnitude of the p-type dopant and within the bottom region an average concentration of hydrogen is less than an average concentration of the p-type dopant by at least one order of magnitude.

In some embodiments, the top region includes a top one half of a thickness of the second layer and the bottom region includes a bottom one half of the thickness of the second layer.

In some embodiments, the top region includes a top one third of a thickness of the second layer and the bottom region includes a bottom one third of the thickness of the second layer.

In some embodiments, an average concentration of hydrogen within the top region is at least one half an order of magnitude greater than an average concentration of hydrogen within the bottom region.

In some embodiments, the p-type dopant comprises magnesium.

In some embodiments, the average concentration of the hydrogen in the top region is greater than 1E+19 atoms/cc and the average concentration of hydrogen in the bottom region is less than 1E+18 atoms/cc.

A substrate comprises a layer comprising gallium nitride (GaN), a deactivation agent, and a p-type dopant. An average concentration of the deactivation agent in a top region of the layer is at least one order of magnitude greater than an average concentration of the deactivation agent in a bottom region of the layer.

In some embodiments, the top region of the layer is an upper one half of a thickness of the layer and the bottom region of the layer is a lower one half of the thickness of the layer.

In some embodiments, the top region of the layer is an upper one third of a thickness of the layer and the bottom region of the layer is a lower one third of the thickness of the layer.

In some embodiments, within the upper one third of the thickness, an average concentration of the deactivation agent is within one order of magnitude of a concentration of the p-type dopant and within the lower one third of the thickness, an average concentration of the deactivation agent is less than an average concentration of the p-type dopant by at least one order of magnitude.

In some embodiments, the average concentration of the deactivation agent in the upper one third of the thickness of the layer is greater than 1E+19 atoms/cc and the average concentration of the deactivation agent in the lower one third of the thickness of the layer is less than 1E+18 atoms/cc.

In some embodiments, the p-type dopant comprises magnesium and the deactivation agent comprises hydrogen.

In some embodiments, the layer is a first layer and the substrate further comprises a second layer on which the first layer is disposed, the second layer comprises aluminum gallium nitride (AlGaN).

In some embodiments, the substrate comprises a third layer disposed below the second layer and comprising gallium nitride (GaN).

In some embodiments, the substrate comprises a fourth layer disposed below the third layer and comprising p-type silicon.

A method of forming a substrate comprises forming a layer comprising gallium nitride (GaN), a deactivation agent, and a p-type dopant. An average concentration of the deactivation agent in a top region of the layer is at least one order of magnitude greater than an average concentration of the deactivation agent in a bottom region of the layer.

In some embodiments, the top region of the layer associated with the method is an upper one half of a thickness of the layer and the bottom region of the layer is a lower one half of the thickness of the layer.

In some embodiments, the top region of the layer associated with the method is an upper one third of a thickness of the layer and the bottom region of the layer is a lower one third of the thickness of the layer.

In some embodiments, within the top region, the average concentration of the deactivation agent associated with the method is within one order of magnitude of a concentration of the p-type dopant and within the bottom region, the average concentration of the deactivation agent is less than an average concentration of the p-type dopant by at least one order of magnitude.

A substrate comprises a layer comprising gallium nitride (GaN), a p-type dopant, and a deactivation agent that deactivates the p-type dopant. A greater quantity of the p-type dopant is deactivated within a top region of the layer than within a bottom region of the layer.

In some embodiments, the top region of the layer is an upper one half of a thickness of the layer and the bottom region of the layer is a lower one half of the thickness of the layer.

In some embodiments, the top region of the layer is an upper one third of a thickness of the layer and the bottom region of the layer is a lower one third of the thickness of the layer.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1A illustrates a simplified partial cross-sectional view of a GaN-based semiconductor substrate that includes a cap layer, according to embodiments of the disclosure;

FIG. 1B illustrates a simplified graph of the atomic concentration of aluminum, hydrogen and a dopant in the cap layer of the substrate shown in FIG. 1A; and

FIG. 1C illustrates steps associated with a method of manufacturing the GaN-based substrate shown in FIG. 1A.

### DETAILED DESCRIPTION

Techniques disclosed herein relate generally to gallium nitride (GaN)-based semiconductor devices. More specifically, techniques disclosed herein relate to forming GaN-based substrates that can be used to form GaN-based transistors, and other semiconductor devices. Various inventive embodiments are described herein, including methods, processes, systems, devices, and the like.

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

In order to better appreciate the features and aspects of the present disclosure, further context for the disclosure is provided in the following section by discussing one particular implementation of a GaN-based semiconductor substrate that can be used to form a transistor according to embodiments of the disclosure. These embodiments are for explanatory purposes only and other embodiments may have different constituent materials, arrangements of layers compositions and the like.

For example, in some embodiments a semiconductor substrate includes a base layer of p-type silicon, a buffer layer of GaN, a barrier layer of AlGaN and a cap layer of p-type GaN that is doped with magnesium. The cap layer may also include a p-type deactivation agent such as, for example, hydrogen. The absolute and relative concentrations of magnesium and hydrogen vary throughout the thickness of the cap layer to provide a transistor with reduced leakage current (e.g., reduced forward gate current) and an improved subthreshold slope (e.g., the transistor blocks current at a reduced voltage below the gate threshold voltage), as explained in more detail below.

In some embodiments a hydrogen concentration in a top region of the p-type GaN layer is at least greater than a concentration of the dopant which results in at least partial deactivation of the dopant in this region. In contrast, the hydrogen concentration in a bottom region of the p-type GaN layer may be significantly below the concentration of the dopant, resulting in a relatively high concentration of active dopant where the cap layer interfaces with the barrier layer (e.g., the channel region) of the transistor.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

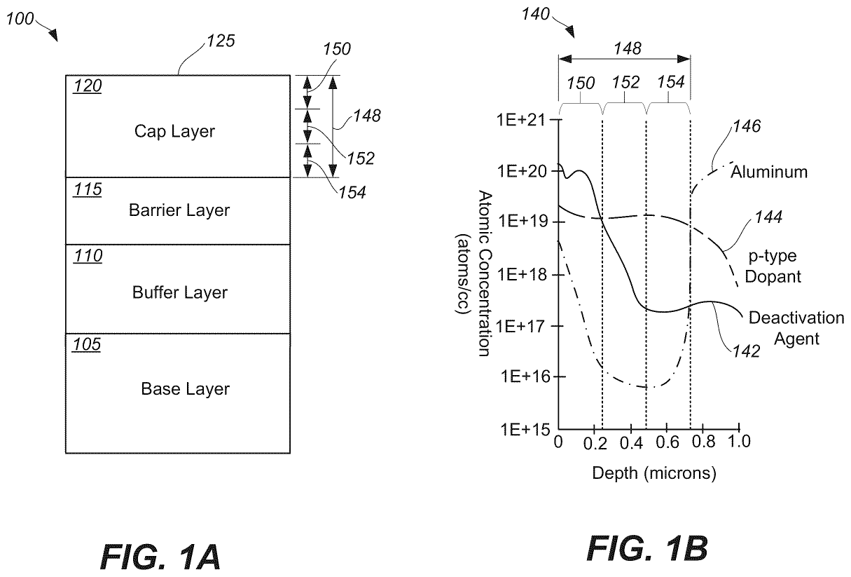

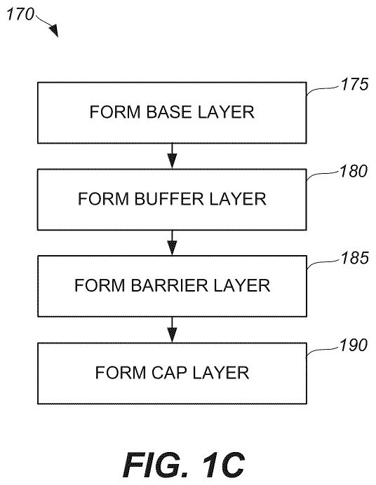

FIG. 1A illustrates a simplified partial cross-sectional view of an example GaN-based semiconductor substrate 100, according to embodiments of the disclosure. FIG. 1B illustrates a simplified graph 140 of the atomic concentration of aluminum, hydrogen and a dopant in a cap layer 120 of the example GaN-based substrate 100 shown in FIG. 1A. FIG. 1C illustrates steps associated with a method 170 of manufacturing the example GaN-based substrate shown in FIG. 1A. FIGS. 1A-1C will be discussed simultaneously below to illustrate features of the disclosure.

As shown in FIG. 1A, example GaN-based semiconductor substrate 100 includes a base layer 105 that is formed in step 175 of method 170 shown in FIG. 1C. In some embodiments base layer 100 may be formed from p-type silicon, silicon, any other suitable type of silicon, silicon carbide, sapphire, aluminum nitride, silicon-on-insulator, or other suitable material and may be between 0.2 mm and 5 mm thick, between 0.5 mm and 3 mm thick, between 0.75 mm and 1.2 mm thick or approximately 1 mm thick.

A buffer layer 110 (shown in FIG. 1A) is disposed on base layer 105 and is formed in step 180 of method 170 shown in FIG. 1C. In some embodiments buffer layer 110 may be formed from GaN or other suitable material including but not limited to, GaN, one or more layers of AlGaN and GaN, a superlattice of AlGaN, a superlatice of AlGaN and GaN, a stack of various III-IV nitride epitaxial layers including, but not limited to binary compounds (e.g., GaN), ternary compounds (e.g., AlGaN) and/or quaternary compounds (e.g., AlInGaN). In some embodiments buffer layer 110 may be between 0.1 micron and 100 microns thick, between 0.5 micron and 50 microns thick, between 1 micron and 5 microns thick or approximately 3 microns thick.

A barrier layer 115 (shown in FIG. 1A) is disposed on buffer layer 110 and is formed in step 185 of method 170 shown in FIG. 1C. In some embodiments barrier layer 115 may be formed from aluminum gallium nitride (AlGaN) where the aluminum percentage may be between 20 and 25 percent or between 15 and 30 percent. In various embodiments, barrier layer 115 may include a composite stack of III nitrides such as, but not limited to, aluminum nitride (AlN), indium nitride (InN) and/or III nitride alloys such as aluminum gallium nitride (AlGaN) and/or aluminum indium gallium nitride (AlInGaN). In one embodiment a composition of the barrier layer is A10.20 Ga0.80 N while in a further embodiment the composition is A10.25 Ga0.75 N. In some embodiments barrier layer 115 is between 5 and 100 nanometers thick, between 10 and 50 nanometers thick, between 15 and 25 nanometers thick or approximately 20 nanometers thick.

A cap layer 120 (shown in FIG. 1A) is disposed on barrier layer 115 and is formed in step 190 of method 170 shown in FIG. 1C. In some embodiments cap layer 120 can be composed of GaN that is doped with a p-type dopant, that can be for example, magnesium, carbon, oxygen, iron or other suitable element. Cap layer 120 can also include one or more deactivation agents, for example, hydrogen, that deactivate the p-type dopant. In some embodiments the dopant concentration and the deactivation agent concentration may vary within a thickness of the cap layer 120 to improve the performance of a transistor formed in the substrate, as described in greater detail in FIG. 1B.

As illustrated in FIG. 1B, graph 140 shows example atomic concentrations of a p-type dopant 144, a deactivation agent 142 and aluminum 146 throughout cap layer 120, where the example barrier layer 115 comprises AlGaN and the example cap layer 120 comprises p-type doped GaN. FIG. 1B is for example only and this disclosure is in no way limited by this illustrative example; more particularly the compositions of the layers, concentrations of elements and the like can be any of those disclosed herein, or variants thereof. The X-axis of graph 140 shows a depth of the cap layer 120 where 0 microns starts at top surface 125 (see FIG. 1A) of cap layer 120 and the cap layer ends where the aluminum 146 concentration from the AlGaN barrier layer 115 sharply increases at approximately 73 microns. As illustrated in FIGS. 1A and 1B, cap layer 120 has a thickness 148 including a top one third 150, a middle one third 152 and bottom top one third 154 (all shown and labeled similarly in FIGS. 1A and 1B).

In this particular example an average concentration of deactivation agent 142 in the top one third 150 of cap layer 120 (e.g., 1.7E+19) is over one-half an order of magnitude greater than the average concentration of the p-type dopant 144 (e.g., 1.1E+19) in the top one third. In the bottom one third 154, the average concentration of the deactivation agent 142 (e.g., 1.3E+17) is more than an order of magnitude less than an average concentration of the p-type dopant 144 (e.g., 1E+19).

More specifically a high concentration of the deactivation agent 142 that is at least as high as a concentration of the p-type dopant 144 effectively deactivates a relatively large percentage of the p-type dopant in the upper region resulting in a lower conductivity of the upper region of the cap layer 120. In contrast, within the bottom one third 154 of the cap layer 120 it may be beneficial for a concentration of the deactivation agent to be substantially reduced as compared to the upper region such that a concentration of the deactivation agent as compared to the p-type dopant 144 is low. This results in an increased portion of the p-type dopant 144 remaining active in the bottom region of the cap layer 120, which is the channel region of the transistor. The effect of these shifts in hydrogen concentration within the cap layer 120 may be, 1) reduced leakage current (e.g., reduced forward gate current) and 2) an improved subthreshold slope (e.g., the device blocks current at a reduced voltage below the gate threshold voltage), which may be improved without adversely affecting other parameters of the transistor.

In further embodiments, the upper region can be one quarter of a thickness of the cap layer 120, one third of a thickness of the cap layer or one half of a thickness of the cap layer, similarly the lower region can be one quarter of a thickness of the cap layer, one third of a thickness of the cap layer or one half of a thickness of the cap layer. In some embodiments, an average concentration of the deactivation agent 142 within the top region is within one order of magnitude of a concentration of the p-type dopant 144, and an average concentration of the deactivation agent within the bottom region is less than an average concentration of the p-type dopant by at least one order of magnitude. In various embodiments an average concentration of the deactivation agent within the top region is at least one half an order of magnitude greater than an average concentration of the deactivation agent within the bottom region. In some embodiments an average concentration of the deactivation agent within the top region is at least one order of magnitude greater than an average concentration of the deactivation agent within the bottom region. In some embodiments the average concentration of the deactivation agent 142 in the top region is greater than 1E+19 atoms/cc and the average concentration of the deactivation agent in the bottom region is less than 1E+18 atoms/cc. In various embodiments an average concentration of the deactivation agent 142 in a top region of the cap layer is at least one order of magnitude greater than an average concentration of the deactivation agent in a bottom region of the layer.

These and other variations in the p-type dopant 144 concentration and the deactivation agent 142 concentration may be formed within the cap layer 120 as it is deposited (in situ) or after it is deposited (ex situ) via exposure to certain chemical species, elevated temperatures, and the like.

As appreciated by one of skill in the art, an average concentration of an element within a particular region can be determined by discretizing the graph of the concentration of the element into a series of discrete concentration values equally spaced across the depth of that particular region, then adding up all of the values and dividing the sum by the number of values. In some embodiments where the atomic concentration is determined via analytical methods such as secondary ion mass spectrometry (SIMS) the atomic concentrations within the first approximately 5 percent to 20 percent of the thickness may be inaccurate due to surface-effects and may be disregarded from average concentration calculations within the top one region. As appreciated by one of ordinary skill in the art having the benefit of this disclosure, graph 140 is for example only and other embodiments will have different thicknesses, compositions, gradients, dopants and the like. Further, it will be appreciated that method 170 is illustrative and that variations and modifications are possible. Steps described as sequential may be executed in parallel, order of steps may be varied, and steps may be modified, combined, added or omitted.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A substrate comprising:
a first layer comprising aluminum gallium nitride (AlGaN);
a second layer comprising gallium nitride (GaN), hydrogen and a p-type dopant, the second layer disposed on the first layer and having a top region disposed above a bottom region, wherein:
within the top region an average concentration of hydrogen is within one order of magnitude of a concentration of the p-type dopant; and
within the bottom region an average concentration of hydrogen is less than an average concentration of the p-type dopant by at least one order of magnitude.

2. The substrate of claim 1, wherein the top region includes a top one half of a thickness of the second layer and wherein the bottom region includes a bottom one half of the thickness of the second layer.

3. The substrate of claim 1, wherein the top region includes a top one third of a thickness of the second layer and wherein the bottom region includes a bottom one third of the thickness of the second layer.

4. The substrate of claim 1, wherein an average concentration of hydrogen within the top region is at least one half an order of magnitude greater than an average concentration of hydrogen within the bottom region.

5. The substrate of claim 1, wherein the p-type dopant comprises magnesium.

6. The substrate of claim 4, wherein the average concentration of the hydrogen in the top region is greater than 1E+19 atoms/cc and wherein the average concentration of hydrogen in the bottom region is less than 1E+18 atoms/cc.

7. A substrate comprising:
a layer comprising gallium nitride (GaN), a deactivation agent and a p-type dopant, wherein an average concentration of the deactivation agent in a top region of the layer is at least one order of magnitude greater than an average concentration of the deactivation agent in a bottom region of the layer.

8. The substrate of claim 7, wherein the top region of the layer is an upper one half of a thickness of the layer and wherein the bottom region of the layer is a lower one half of the thickness of the layer.

9. The substrate of claim 7, wherein the top region of the layer is an upper one third of a thickness of the layer and wherein the bottom region of the layer is a lower one third of the thickness of the layer.

10. The substrate of claim 9, wherein within the upper one third of the thickness an average concentration of the deactivation agent is within one order of magnitude of a concentration of the p-type dopant; and
wherein within the lower one third of the thickness an average concentration of the deactivation agent is less than an average concentration of the p-type dopant by at least one order of magnitude.

11. The substrate of claim 9, wherein the average concentration of the deactivation agent in the upper one third of the thickness of the layer is greater than 1E+19 atoms/cc and wherein an average concentration of the deactivation agent in the lower one third of the thickness of the layer is less than 1E+18 atoms/cc.

12. The substrate of claim 7, wherein the p-type dopant comprises magnesium and wherein the deactivation agent comprise hydrogen.

13. The substrate of claim 7, wherein the layer is a first layer, the substrate further comprising a second layer on which the first layer is disposed, wherein the second layer comprises aluminum gallium nitride (AlGaN).

14. The substrate of claim 13, further comprising a third layer disposed below the second layer and comprising gallium nitride (GaN).

15. The substrate of claim 14, further comprising a fourth layer disposed below the third layer and comprising p-type silicon.

16. A method of forming a substrate, the method comprising:
forming a layer comprising gallium nitride (GaN), a deactivation agent and a p-type dopant, wherein an average concentration of the deactivation agent in a top region of the layer is at least one order of magnitude greater than an average concentration of the deactivation agent in a bottom region of the layer.

17. The method of claim 16, wherein the top region of the layer is an upper one half of a thickness of the layer and wherein the bottom region of the layer is a lower one half of the thickness of the layer.

18. The method of claim 16, wherein the top region of the layer is an upper one third of a thickness of the layer and wherein the bottom region of the layer is a lower one third of the thickness of the layer.

19. The method of claim 18, wherein within the top region the average concentration of the deactivation agent is within one order of magnitude of a concentration of the p-type dopant; and
wherein within the bottom region the average concentration of the deactivation agent is less than an average concentration of the p-type dopant by at least one order of magnitude.

20. A substrate comprising:
a layer comprising gallium nitride (GaN), a p-type dopant and a deactivation agent that deactivates the p-type dopant, wherein a greater quantity of the p-type dopant is deactivated within a top region of the layer than within a bottom region of the layer.

21. The substrate of claim 20, wherein the top region of the layer is an upper one half of a thickness of the layer and wherein the bottom region of the layer is a lower one half of the thickness of the layer.

22. The substrate of claim 20, wherein the top region of the layer is an upper one third of a thickness of the layer and wherein the bottom region of the layer is a lower one third of the thickness of the layer.
